(19) United States
(12) Patent Application Publication
(10) Pub. No.: US 2016/0064435 A1
(43) Pub. Date: Mar. 3, 2016

(54) PHOTO SENSOR AND MANUFACTURING METHOD THEREOF

(71) Applicant: KABUSHIKI KAISHA TOSHIBA, Tokyo (JP)

(72) Inventor: Moto YABUKI, Yokkaichi Mie (JP)

(73) Assignee: KABUSHIKI KAISHA TOSHIBA, Tokyo (JP)

(21) Appl. No.: 14/613,932

(22) Filed: Feb. 4, 2015

Related U.S. Application Data
(60) Provisional application No. 62/045,342, filed on Sep. 3, 2014.

(51) Int. Cl. H01L 27/146

(52) U.S. Cl. CPC H01L 27/14621; H01L 27/14625; H01L 27/14629; H01L 27/14643; H01L 27/14685

(57) ABSTRACT

A photo sensor according to an embodiment includes a semiconductor substrate. A plurality of photodiodes are provided on a first surface of the semiconductor substrate. A plurality of photodetective filters corresponding to the photodiodes are provided on a second surface of the semiconductor substrate opposite to the first surface. A plurality of lenses correspond to the photodetective filters so as to respectively cover the photodetective filters. Protruding portions protrude on the second surface between adjacent ones of the photodetective filters.

### CROSS REFERENCE TO RELATED APPLICATIONS

This application is based upon and claims the benefit of priority from the prior U.S. Provisional Patent Application No. 62/045,342, filed on Sep. 3, 2014, the entire contents of which are incorporated herein by reference.

### FIELD

The embodiments of the present invention relate to a photo sensor and a manufacturing method thereof.

### BACKGROUND

A back side illumination (hereinafter, also BSI) image sensor has been conventionally used as a high performance CMOS (Complementary Metal Oxide Semiconductor) image sensor. The BSI image sensor receives light from the side of a back surface of a semiconductor substrate opposite to a front surface thereof on which elements such as photodiodes and control transistors are formed and detects the received light.

At a manufacturing step of the BSI image sensor, the back surface of the semiconductor substrate is polished up to the vicinity of the photodiodes by a CMP (Chemical Mechanical Polishing) method or the like to receive light from the back surface of the semiconductor substrate. However, when the back surface of the semiconductor substrate is polished, flaws or contaminations occur on the back surface of the semiconductor substrate, which leads to degradation of the photodiodes.

### BRIEF DESCRIPTION OF THE DRAWINGS

FIG. 1 is a cross-sectional view showing an example of a configuration of a photo sensor 1 according to a first embodiment;

FIGS. 2 to 7 are cross-sectional views showing an example of the manufacturing method of the photo sensor 1 according to the first embodiment;

FIG. 8 is a cross-sectional view showing an example of a configuration of a photo sensor 2 according to a second embodiment;

FIGS. 9 to 11 are cross-sectional views showing an example of the manufacturing method of the photo sensor 2 according to the second embodiment;

FIG. 12 is a cross-sectional view showing an example of a configuration of the photo sensor 1 according to a first modification of the first embodiment;

FIG. 13 is a cross-sectional view showing an example of a configuration of the photo sensor 1 according to a second modification of the first embodiment;

FIG. 14 is a cross-sectional view showing an example of a configuration of the photo sensor 2 according to a third modification of the second embodiment;

FIG. 15 is a cross-sectional view showing an example of a configuration of the photo sensor 2 according to a fourth modification of the second embodiment; and

FIG. 16 is a cross-sectional view showing an example of a configuration of the photo sensor 1 according to a fifth modification of the first embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a top surface of a semiconductor substrate or a direction of a back surface of a semiconductor substrate is assumed as “an upper direction”. Therefore, the term “upper direction” or “lower direction” occasionally differs from an upper direction or a lower direction based on a gravitational acceleration direction.

A photo sensor according to an embodiment includes a semiconductor substrate. A plurality of photodiodes are provided on a first surface of the semiconductor substrate. A plurality of photodetective filters corresponding to the photodiodes are provided on a second surface of the semiconductor substrate opposite to the first surface. A plurality of lenses correspond to the photodetective filters so as to respectively cover the photodetective filters. Protruding portions protrude on the second surface between adjacent ones of the photodetective filters.

### First Embodiment

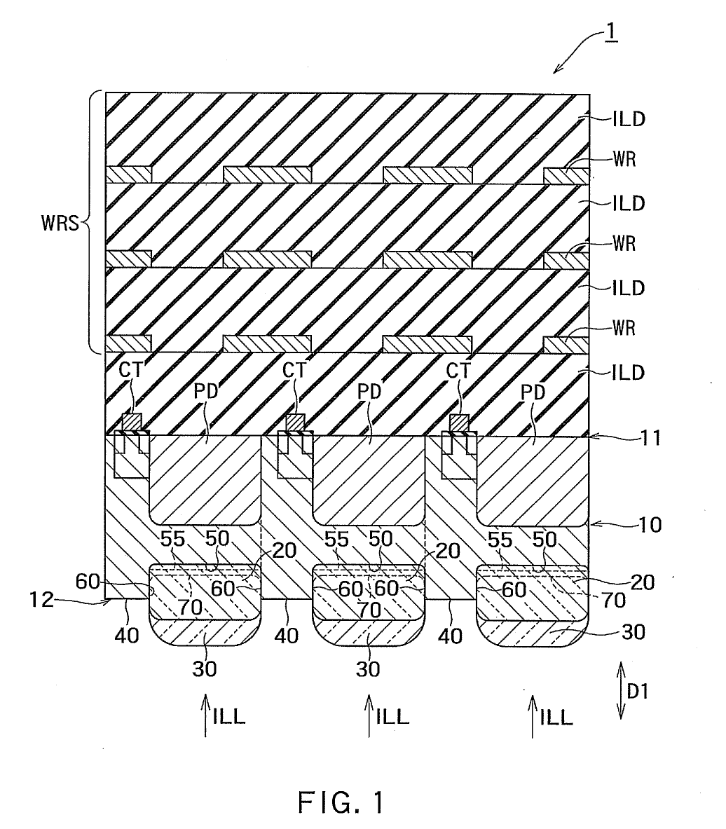

FIG. 1 is a cross-sectional view showing an example of a configuration of a photo sensor 1 according to a first embodiment. The photo sensor 1 includes a semiconductor substrate 10, a plurality of photodiodes PD, a plurality of control transistors CT, a multilayer wiring structure WRS, color filters 20, lenses 30, substrate protruding portions 40, and antireflection films 55.

The photo sensor 1 is, for example, a BSI CMOS image sensor and receives incident light ILL from a back surface of the semiconductor substrate 10 and detects the incident light ILL. The semiconductor substrate 10 is, for example, a silicon substrate.

The photodiodes PD have a PN junction or a PIN structure and receive the incident light (an optical signal) ILL to generate power (an electrical signal) due to a photovoltaic effect. The photodiodes PD constitutes pixels, respectively.

The control transistors CT are electrically connected between the photodiodes PD and the multilayer wiring structure WRS, respectively, and are controlled to be ON/OFF. The control transistors CT can transmit the electrical signals generated by the photodiodes PD to the multilayer wiring structure WRS, respectively. In the first embodiment, one photodiode PD and one control transistor CT constitute one pixel. In the first embodiment, one control transistor CT is provided for each pixel. As necessary, however, a plurality of control transistors CT can be provided for each pixel or one control transistor CT can be provided for a plurality of pixels.

The multilayer wiring structure WRS is formed by alternately stacking wiring layers WR and interlayer dielectric films ILD. The wiring layers WR of the multilayer wiring structure WRS are formed to output the electrical signals from the control transistors CT to outside of the photo sensor 1.

The photodiodes PD, the control transistors CT, and the multilayer wiring structure WRS are provided on a front surface (first surface) 11 of the semiconductor substrate 10.

The color filters 20 serving as photodetective filters are provided on the side of a back surface (second surface) 12 of the semiconductor substrate 10 and correspond to the photodiodes PD, respectively. The color filters 20 are filled in recesses 50 located between adjacent ones of the substrate protruding portions 40, respectively. Adjacent ones of the color filters 20 are optically separated from each other by the substrate protruding portions 40, respectively. The color filters 20 are made of, for example, a resin and contain pigments to transmit light of specific colors (red, green, and blue, for example) of the incident light ILL, respectively. For example, the color filters 20 for three pixels shown in FIG. 1 can contain pigments of red, green, and blue, respectively.

The lenses 30 are provided to correspond to the color filters 20 and are provided to cover the color filters 20, respectively. The lenses 30 are made of, for example, a transparent resin. The lenses 30 can contain pigments instead of the color filters 20 or as well as the color filters 20.

The protruding portions 40 are protruded on the side of the back surface 12 of the semiconductor substrate 10 between adjacent ones of the color filters 20. That is, the protruding portions 40 are protruded from the back surface 12 of the semiconductor substrate 10 on both sides of each recess 50 or on both sides of each color filter 20. The substrate protruding portions 40 are provided as parts of the semiconductor substrate 10 and are made of, for example, silicon. The back surface 12 of the semiconductor substrate 10 is formed in a concave-convex shape by the recesses 50 and the substrate protruding portions 40. Because the back surface 12 of the semiconductor substrate 10 is formed in the concave-convex shape, interfaces 60 between side surfaces of the color filters 20 and side surfaces of the substrate protruding portions 40 extend in a direction substantially parallel to an incidence direction of the incident light ILL. That is, the interfaces 60 extend in a direction D1 orthogonal to the back surface 12 of the semiconductor substrate 10. Therefore, when the incident light ILL enters in a direction tilted with respect to the direction D1 (an arrow direction in FIG. 1), the semiconductor substrate 10 can reflect the incident light ILL at the interfaces 60. Accordingly, the substrate protruding portions 40 optically separate adjacent ones of the color filters 20 from each other.

Transparent bodies 70 can be further provided between the color filters 20 and the recesses 50 of the semiconductor substrate 10, respectively. When the incident light ILL is excessively reflected on bottoms of the recesses 50, the antireflection films 55 can be further provided between the bottoms of the recesses 50 and the transparent bodies 70, respectively. This suppresses reflection of the incident light ILL on the bottoms of the recesses 50.

In the first embodiment, the back surface 12 of the semiconductor substrate 10 is formed in the concave-convex shape by the recesses 50 and the semiconductor protruding portions 40. With this concave-convex shape, the interfaces 60 extending in the direction substantially parallel to the incidence direction of the incident light ILL are formed by the side surfaces of the color filters 20 and the side surfaces of the substrate protruding portions 40, respectively. The semiconductor substrate 10 at the interfaces 60 reflects the incident light ILL traveling in a tilted direction and thus forms optical paths of the incident light ILL. That is, the substrate protruding portions 40 and the recesses 50 form the optical paths corresponding to the photodiodes PD, respectively, and separate the optical paths from each other. Accordingly, the incident light ILL having passed through the lenses 30 and the color filters 20 can be guided to the photodiodes PD corresponding to the pixels and be suppressed from erroneously entering the photodiodes PD of adjacent pixels.

A manufacturing method of the photo sensor 1 according to the first embodiment is explained next.

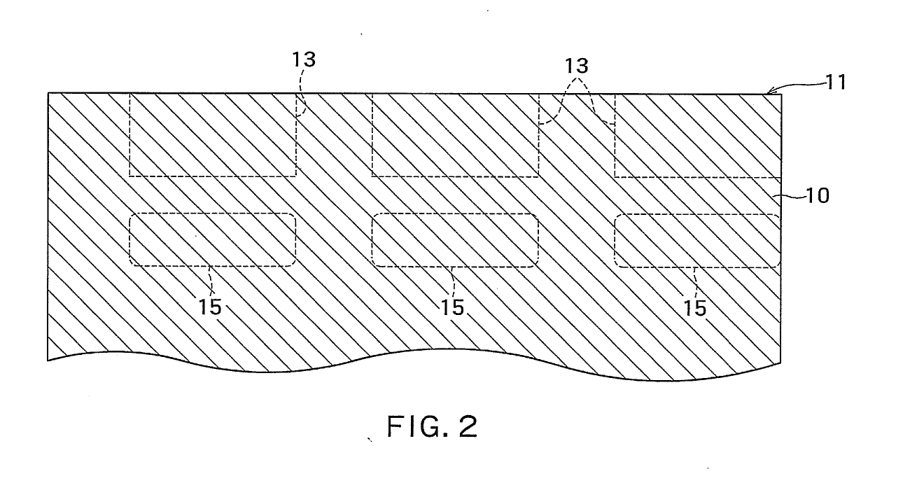

FIGS. 2 to 7 are cross-sectional views showing an example of the manufacturing method of the photo sensor 1 according to the first embodiment. As shown in FIG. 2, oxygen 15 is first introduced below photodiode formation regions 13 in the front surface 11 of the semiconductor substrate 10. At that time, ions of the oxygen 15 are selectively implanted to correspond to the photodiode formation regions 13 using a lithography technique. The oxygen 15 is not introduced to parts of the semiconductor substrate 10 located between adjacent ones of the photodiode formation areas 13.

An implantation depth of the oxygen 15 (a depth from the front surface 11) is set according to a thickness of the photo sensor 1 to be formed. This is because silicon dioxide films 17 formed by the oxygen 15 function as a stopper at a polishing step of the back surface 12 of the semiconductor substrate 10 and determine the thickness of the photo sensor 1, which will be explained in detail later. The implantation depth of the oxygen 15 is, for example, between 1 micrometer and 3 micrometers from the front surface 11.

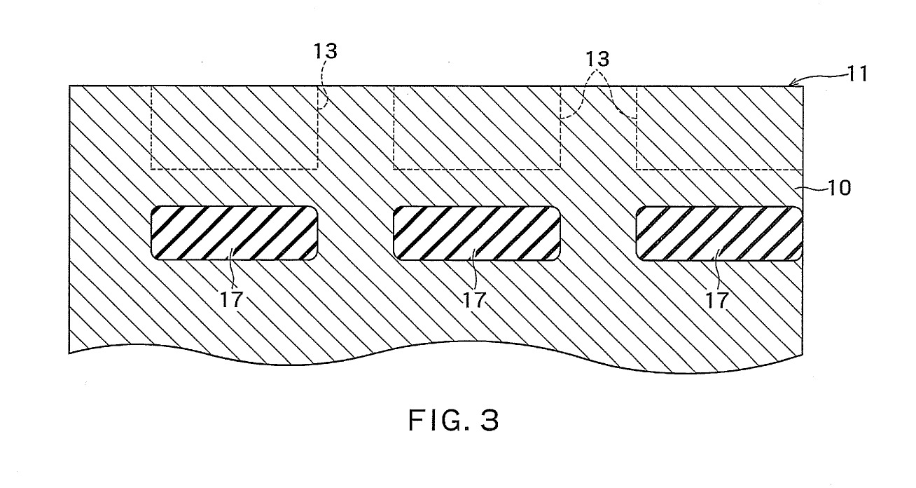

The semiconductor substrate 10 is then thermally treated to combine and agglutinate the semiconductor substrate 10 and the oxygen 15 with each other. For example, the semiconductor substrate 10 is heated to a temperature of about 1050 degrees. The silicon dioxide films 17 are thereby formed below the photodiode formation regions 13, respectively, as shown in FIG. 3. The silicon dioxide films 17 are formed in a separated state with respect to the photodiode formation regions 13, respectively. This is to form the substrate protruding portions 40 and the recesses 50 explained later.

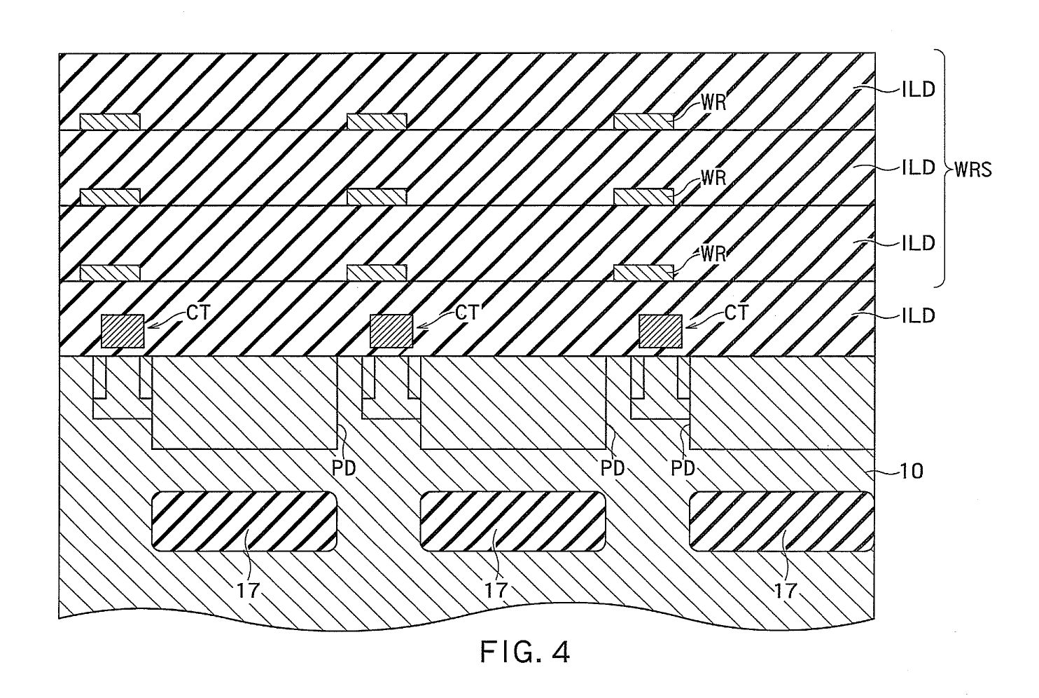

The photodiodes PD and the control transistors CT are then formed on the front surface 11 of the semiconductor substrate 10 as shown in FIG. 4. At that time, the photodiodes PD are formed in the photodiode formation regions 13 to correspond to the silicon dioxide films 17, respectively. The control transistors CT are formed to correspond to the photodiodes PD, respectively.

An interlayer dielectric film ILD is then deposited on the photodiodes PD and the control transistors CT as shown in FIG. 4. A wiring layer WR is then formed on the interlayer dielectric film ILD or a wiring layer WR is embedded in the interlayer dielectric film ILD. By repeatedly forming the interlayer dielectric films ILD and the wiring layers WR in this way, the multilayer wiring structure WRS is formed.

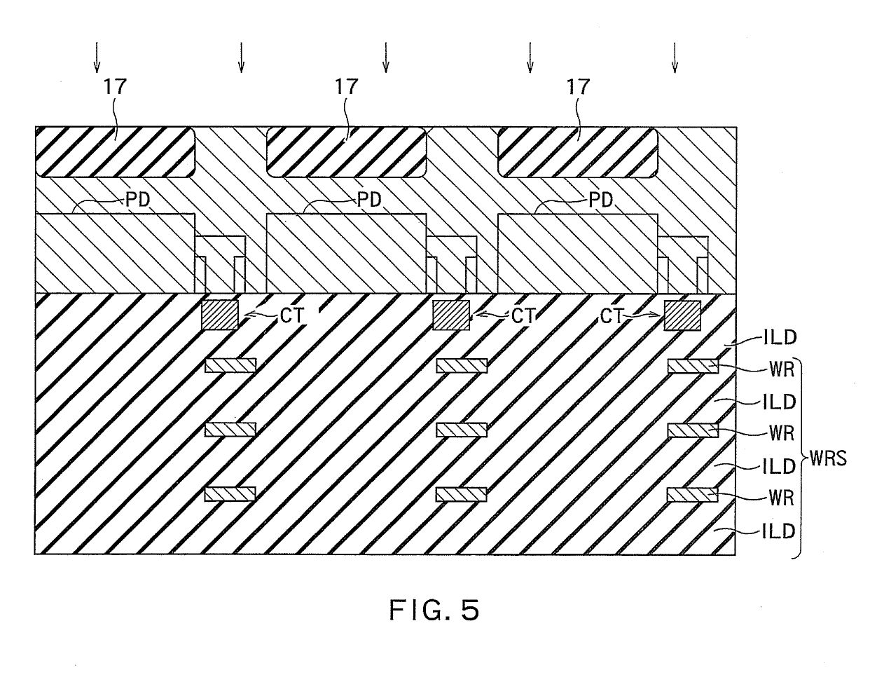

The back surface 12 of the semiconductor substrate 10 is then polished by the CMP method. At that time, the back surface 12 of the semiconductor substrate 10 is entirely polished until the silicon dioxide films 17 are exposed as shown in FIG. 5. As described above, the silicon dioxide films 17 function as a stopper at the polishing step.

If the silicon dioxide films 17 are not provided, the polishing amount of the semiconductor substrate 10 varies when the semiconductor substrate 10 is polished by the CMP method. In this case, the thickness of the semiconductor substrate 10 varies within a plane after polishing. Furthermore, the plane of the semiconductor substrate 10 polished by the CMP method contains many crystal defects and metallic impurities. The variations in the thickness of the semiconductor substrate 10 or the crystal defects and metallic impurities lead to variations in characteristics of the photodiodes PD or deterioration in the characteristics.

On the other hand, according to the first embodiment, the silicon dioxide films 17 are provided at a predetermined depth position and function as a stopper at the polishing step. Therefore, the variations in the polishing amount of the semiconductor substrate 10 are suppressed and the thickness of the semiconductor substrate 10 becomes substantially uniform within the plane after polishing. Because the silicon dioxide films 17 are provided to correspond to the photodiodes PD, the photodiodes PD are protected by the silicon dioxide films 17 on the side of the back surface 12, respectively. Therefore, parts of the semiconductor substrate 10 between the photodiodes PD and the silicon dioxide films 17 contain few crystal defects or metallic impurities at this time.

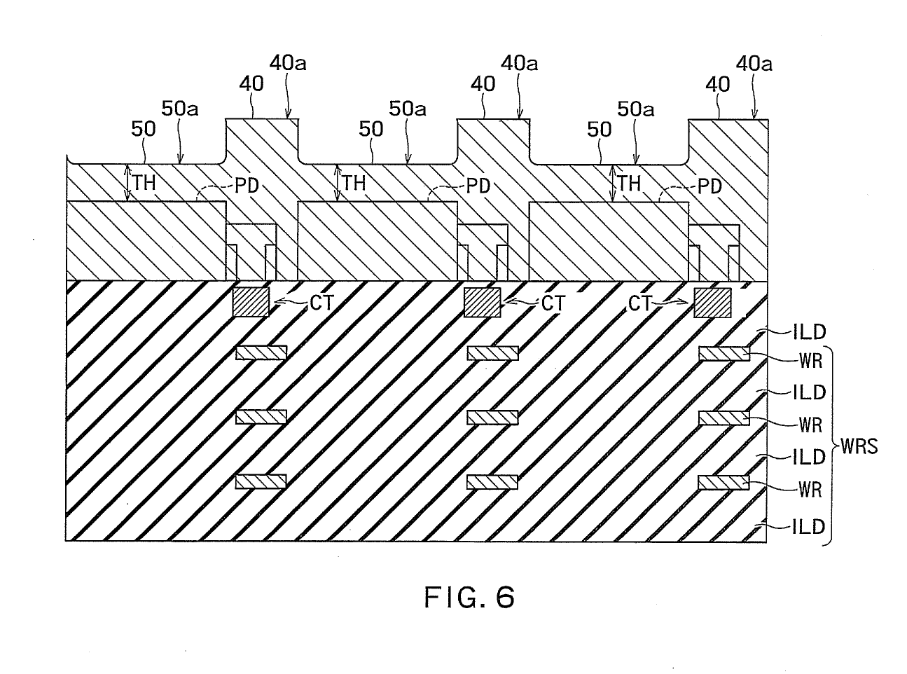

The silicon dioxide films 17 are then removed by a wet etching method as shown in FIG. 6. The recesses 50 corresponding to the photodiodes PD, respectively, are thereby formed. The substrate protruding portions 40 are formed between adjacent ones of the recesses 50, respectively.

In this example, the recesses 50 are formed by removing the silicon dioxide films 17 by wet etching. Therefore, bottom surfaces 50a of the recesses 50 have fewer crystal defects or contaminations than front surfaces 40a of the substrate protruding portions 40 polished by the CMP method. The bottom surfaces 50a of the recesses 50 are regions through which the incident light ILL on the photodiodes PD passes. Therefore, the fact that the bottom surfaces 50a of the recesses 50 have fewer crystal defects or contaminations enhances sensitivities or efficiencies of the photodiodes PD. Meanwhile, the front surfaces 40a of the substrate protruding portions 40 are regions through which the incident light ILL does not pass and no problem occurs even when some crystal defects are contained therein. Instead, when there are some crystal defects in the front surfaces 40a, the crystal defects absorb contaminants such as metals located around the front surfaces 40a. Accordingly, contaminants in regions through which the incident light ILL passes (for example, regions of the semiconductor substrate 10 between the photodiodes PD and the recesses 50) can be reduced. As a result, degradation of the photodiodes PD can be suppressed.

The recesses 50 are formed by removing the silicon dioxide films 17. Therefore, thicknesses TH of the semiconductor substrate 10 between the recesses 50 and the photodiodes PD are not determined by the polishing step of the back surface 12 but are determined by formation positions of the silicon dioxide films 17 (introduction positions of the oxygen 15), respectively. Therefore, when the oxygen 15 is implanted accurately to a uniform depth, the thicknesses TH of the semiconductor substrate 10 can be also formed uniformly. As described above, because the parts the semiconductor substrate 10 between the recesses 50 and the photodiodes PD are regions through which the incident light ILL passes, the uniform thickness enables the sensitivities or efficiencies of the photodiodes PD to be uniform.

The semiconductor substrate 10 is then thermally treated, thereby causing the front surfaces 40a to absorb the contaminants. For example, the semiconductor substrate 10 is heated to a temperature of about 750 degrees. In this way, the crystal defects in the front surfaces 40a absorb the contaminants such as metals located therearound. The contaminants in the regions through which the incident light ILL passes can be thereby reduced as described above.

The antireflection films 55 and the transparent bodies 70 are then formed on the bottom surfaces 50a of the recesses 50, respectively, as necessary. When the antireflection films 55 are formed not only on the bottom surfaces 50a of the recesses 50 but also on the side surfaces of the recesses 50 (the interfaces 60), it is preferable to further provide reflection films on the antireflection films 55 formed on the side surfaces of the recesses 50, respectively. This is because the incident light ILL can be thereby reflected on the interfaces 60.

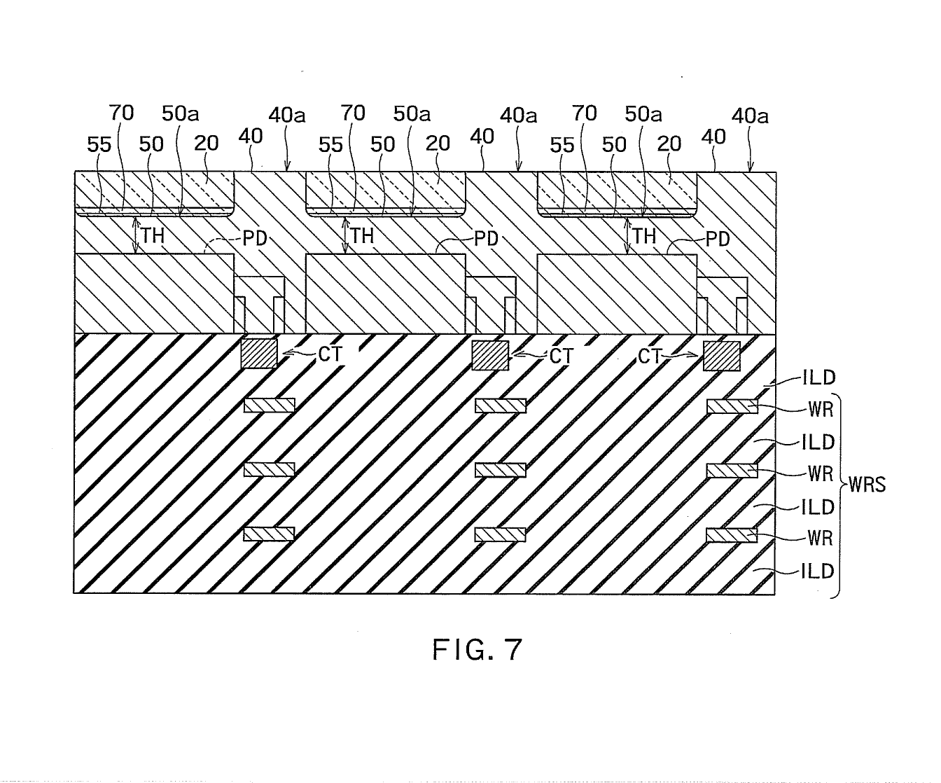

The color filters 20 are then filled in the recesses 50, respectively, as shown in FIG. 7. It suffices to fill therein color filters of R, G, and B in turn. The lenses 30 are then formed on the color filters 20, respectively, as shown in FIG. 1. The photo sensor 1 according to the first embodiment is thereby completed.

As described above, according to the first embodiment, the silicon dioxide films 17 are provided at a predetermined depth and function as a stopper at the polishing step. Therefore, variations in the polishing amount of the semiconductor substrate 10 are suppressed and the thickness of the semiconductor substrate 10 becomes substantially uniform within the plane after polishing.

Furthermore, the recesses 50 are formed by removing the silicon dioxide films 17 by wet etching. Therefore, the bottom surfaces 50a of the recesses 50 have relatively few crystal defects or contaminations. Accordingly, the sensitivities or efficiencies of the photodiodes PD are enhanced.

Meanwhile, because there are crystal defects in the front surfaces 40a of the substrate protruding portions 40, the crystal defects absorb contaminants such as metals located around the front surfaces 40a. The contaminants in the regions through which the incident light ILL passes can be thereby reduced and degradation of the photodiodes PD can be suppressed.

Furthermore, according to the first embodiment, the thicknesses TH of the semiconductor substrate 10 between the recesses 50 and the photodiodes PD are determined by the formation positions of the silicon dioxide films 17 (the introduction positions of the oxygen 15), respectively. Therefore, when the oxygen 15 is introduced accurately to a uniform depth, the thicknesses TH of the semiconductor substrate 10 can be also formed uniformly. Accordingly, the optical amounts of the incident light ILL passing through the semiconductor substrate 10 between the recesses 50 and the photodiodes PD also become substantially uniform and thus the sensitivities or efficiencies of the photodiodes PD can be set uniform among the pixels.

Further, in the first embodiment, the back surface 12 of the semiconductor substrate 10 is formed in the concave-convex shape by the recesses 50 and the substrate protruding portions 40. With the concave-convex shape, the interfaces 60 are formed by the side surfaces of the color filters 20 and the side surfaces of the substrate protruding portions 40 and the incident light ILL can be guided to the photodiodes PD corresponding to the pixels, respectively.

### Second Embodiment

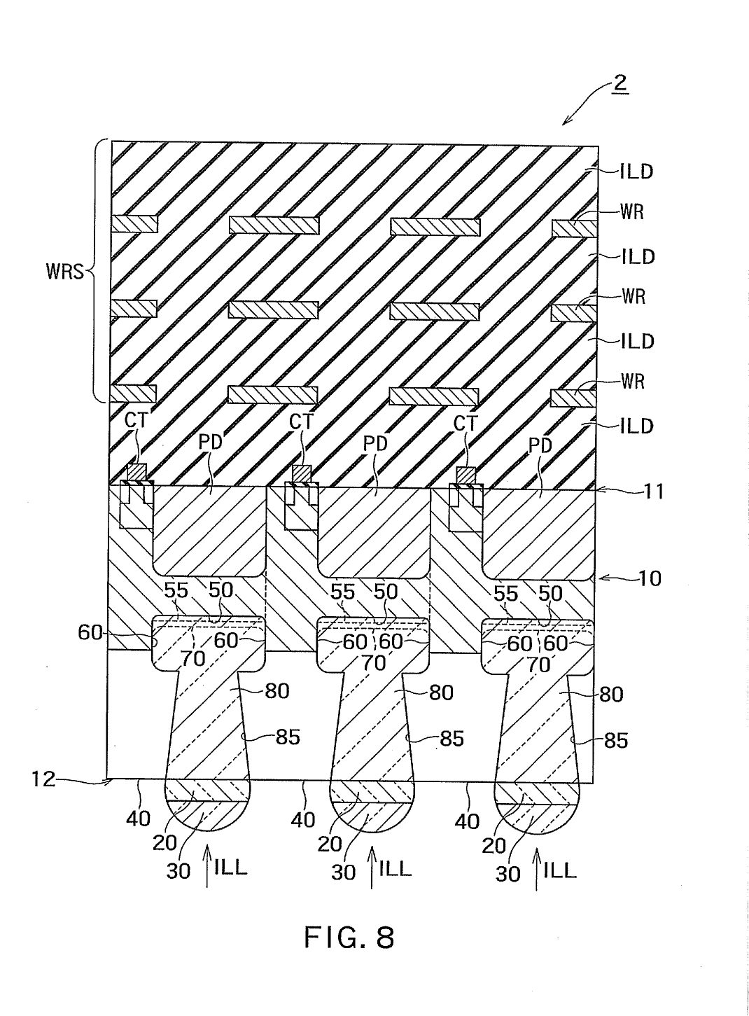

FIG. 8 is a cross-sectional view showing an example of a configuration of a photo sensor 2 according to a second embodiment. The photo sensor 2 is different from the photo sensor 1 according to the first embodiment in including waveguides 80.

The waveguides 80 are provided between adjacent ones of the substrate protruding portions 40, respectively. The waveguides 80 correspond to the recesses 50 and extend from the recesses 50 to the color filters 20, respectively. The waveguides 80 are formed of, for example, a transparent resin. Associated with the length (the depth) of the waveguides 80, the substrate protruding portions 40 are formed thicker. The depth of the waveguides 80 and the recesses 50 (the thickness of the substrate protruding portions 40) can be determined based on the focal length of the lenses 30.

The waveguides 80 are formed longer (deeper) than the interfaces 60. Therefore, the photo sensor 2 can more effectively guide the incident light ILL for the pixels to the photodiodes PD corresponding to the pixels, respectively. That is, it is possible to more effectively suppress the incident light ILL from mixing into other pixels. Interfaces 85 between the waveguides 80 and the semiconductor substrate 10 thus reflect the incident light ILL and suppress the incident light ILL from mixing into other pixels.

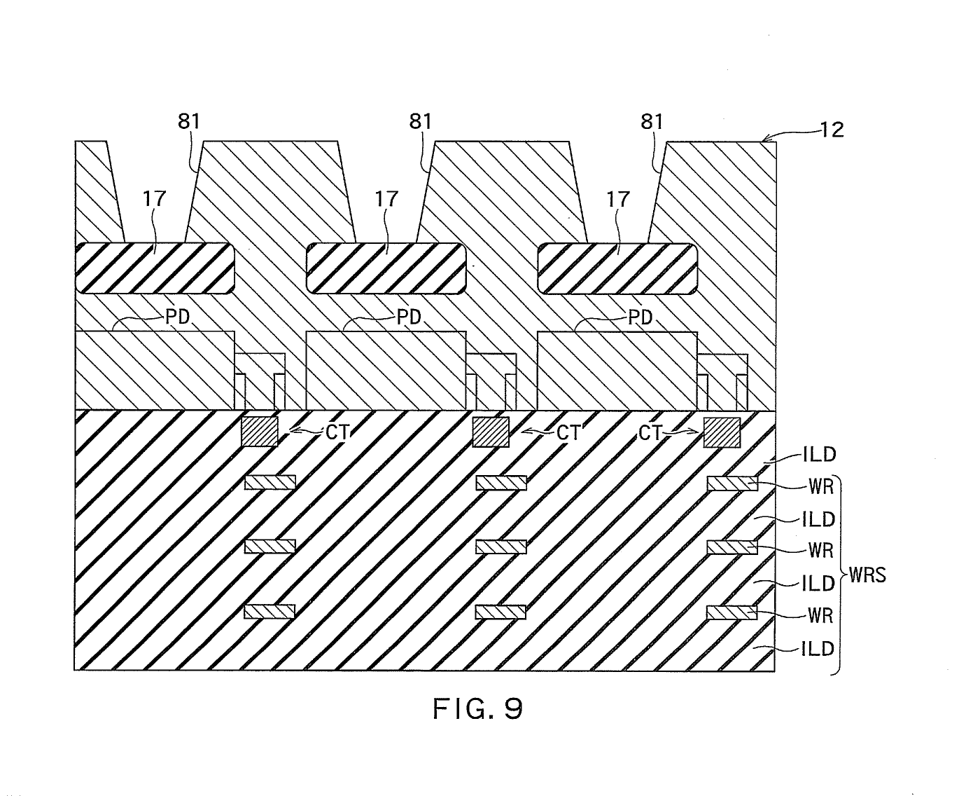

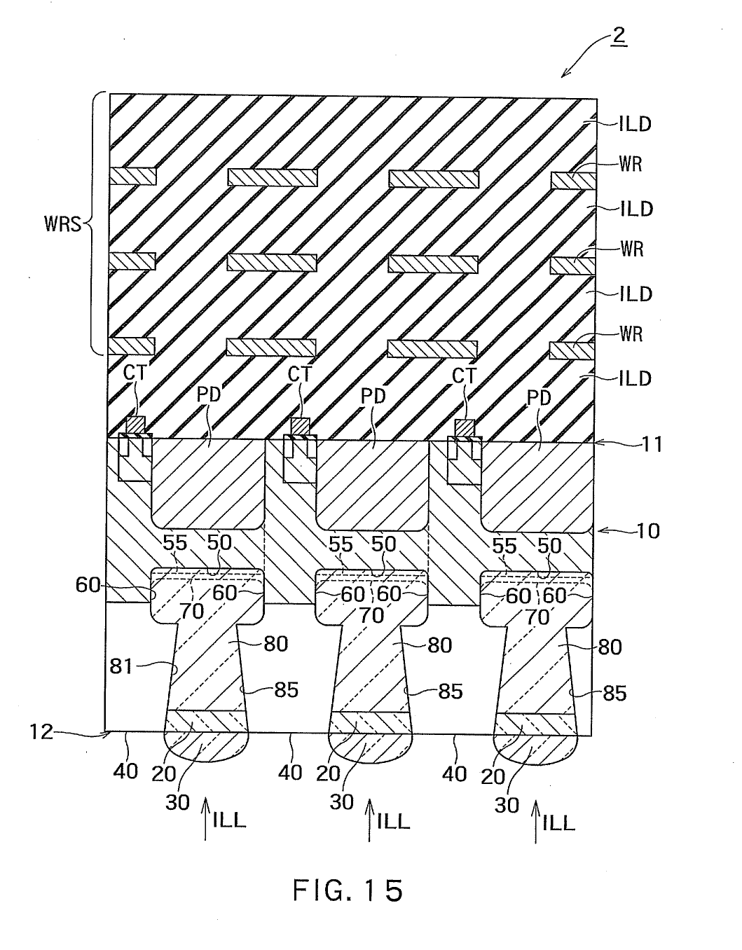

In the second embodiment, the color filters 20 are provided outside of waveguide holes 81 shown in FIG. 9. However, the color filters 20 can be provided inside of the waveguide holes 81 as shown in FIG. 15. In this case, the color filters 20 also function as parts of the waveguides 80.

Because the waveguides 80 are provided separately from the recesses 50 in the second embodiment, the recesses 50 do not always need to be provided to correspond to the photodiodes PD, respectively, and can be provided to correspond to a plurality of photodiodes PD in common. In this case, it suffices to implant the oxygen 15 to the entire surface of the semiconductor substrate 10 at the step of implanting ions of the oxygen 15 shown in FIG. 2 without using the lithography technique.

Other configurations of the second embodiment can be identical to corresponding ones of the first embodiment. Therefore, the second embodiment can also achieve effects identical to those of the first embodiment.

A manufacturing method of the photo sensor 2 according to the second embodiment is explained next.

FIGS. 9 to 11 are cross-sectional views showing an example of the manufacturing method of the photo sensor 2 according to the second embodiment. Steps explained with reference to FIGS. 2 to 4 are first performed.

As explained with reference to FIG. 5, the back surface 12 of the semiconductor substrate 10 is then polished by the CMP method. At this time, however, the back surface 12 is not polished until the silicon dioxide films 17 are exposed and polishing is stopped in a state where the semiconductor substrate 10 covers the silicon dioxide films 17. The thickness of the semiconductor substrate 10 between the silicon dioxide films 17 and the back surface 12 corresponds to the depth of the waveguides 80.

Parts of the semiconductor substrate 10 in formation regions of the waveguides 80 are selectively etched using the lithography technique and an RIE (Reactive Ion Etching) method. The waveguide holes 81 are thereby formed from the back surface 12 of the semiconductor substrate 10 to the silicon dioxide films 17 as shown in FIG. 9. At that time, the silicon dioxide films 17 function as a stopper.

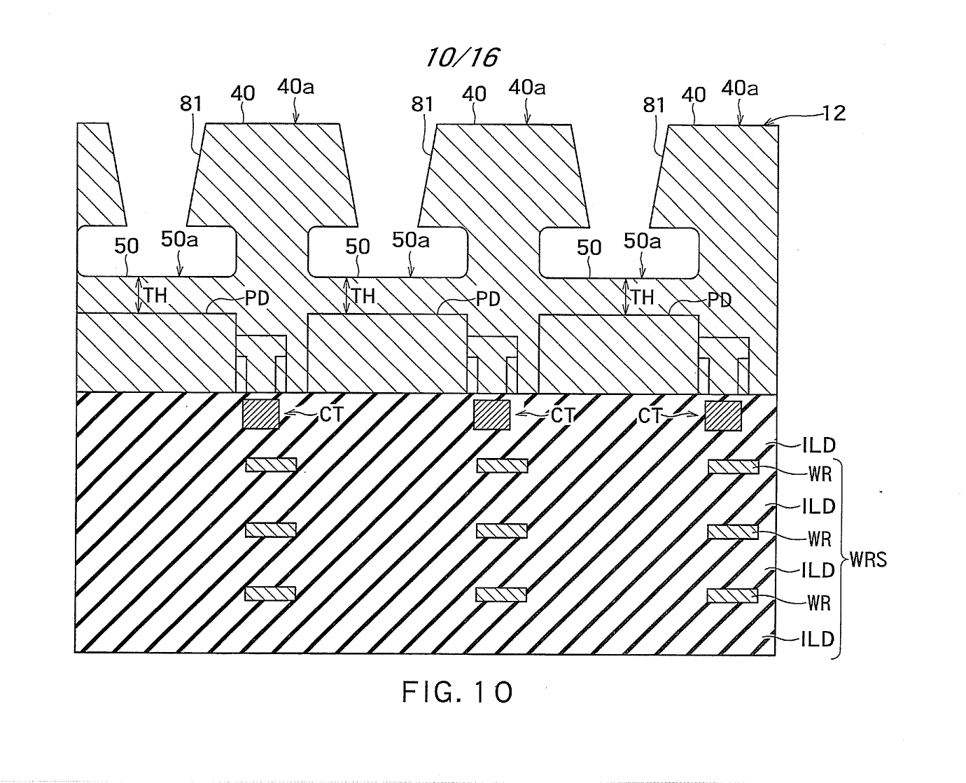

The silicon dioxide films 17 are then removed using the wet etching method as shown in FIG. 10. The recesses 50 corresponding to the photodiodes PD, respectively, are thereby formed. The waveguide holes 81 communicate with the recesses 50, respectively. The substrate protruding portions 40 are formed between adjacent ones of the waveguide holes 81 and the recesses 50, respectively.

In this example, the recesses 50 are formed by removing the silicon dioxide films 17 by wet etching. Therefore, similarly to the first embodiment, the bottom surfaces 50a of the recesses 50 have fewer crystal defects or contaminations than the front surfaces 40a of the substrate protruding portions 40 polished by the CMP method. This enhances the sensitivities or efficiencies of the photodiodes PD. Meanwhile, the front surfaces 40a of the substrate protruding portions 40 are regions through which the incident light ILL does not pass and no problem occurs even when some crystal defects are contained therein. Instead, when the front surfaces 40a of the substrate protruding portions 40 have crystal defects, the crystal defects absorb contaminants such as metals located around the front surfaces 40a. As a result, degradation of the photodiodes PD can be suppressed.

Furthermore, the recesses 50 are formed by removing the silicon dioxide films 17. Therefore, the thicknesses TH of the semiconductor substrate 10 between the recesses 50 and the photodiodes PD are determined by the formation positions of the silicon dioxide films 17 (the introduction positions of the oxygen 15), respectively. Therefore, when the oxygen 15 is implanted accurately to a uniform depth, the thicknesses TH of the semiconductor substrate 10 can be also formed uniformly. This enables to set the sensitivities or efficiencies of the photodiodes PD to be uniform.

The semiconductor substrate 10 is then thermally treated, thereby causing the front surfaces 40a to absorb contaminants. For example, the semiconductor substrate 10 is heated to a temperature of about 750 degrees. Accordingly, the crystal defects in the front surfaces 40a absorb the contaminants such as metals located therearound. In this way, the contaminants in the region through which the incident light ILL passes can be reduced as described above.

The antireflection films 55 and the transparent bodies 70 are then formed on the bottom surfaces 50a of the recesses 50, respectively, as necessary.

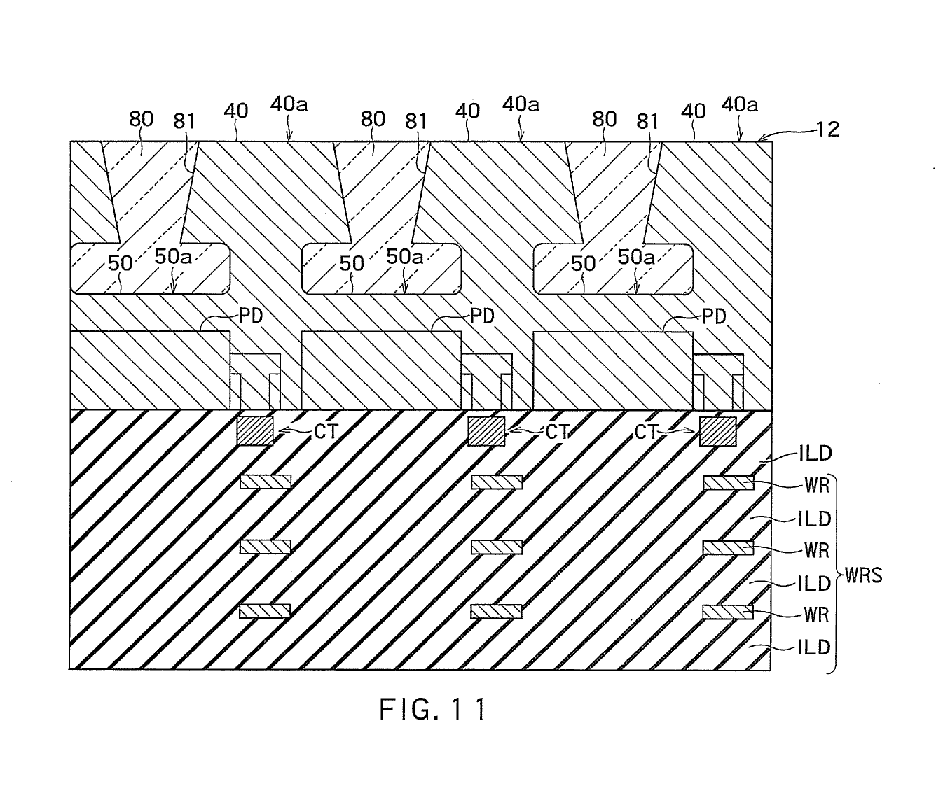

A transparent resin is then filled in the recesses 50 and the waveguide holes 81 as shown in FIG. 11. The waveguides 80 are thereby formed.

The color filters 20 and the lenses 30 are then formed on the waveguides 80, respectively, as shown in FIG. 8. The photo sensor 2 according to the second embodiment is thereby completed.

In this way, according to the second embodiment, the photo sensor 2 including the waveguides 80 corresponding to the photodiodes PD, respectively, can be formed. The waveguides 80 are formed deeper than the recesses 50. Therefore, the photo sensor 2 can more accurately guide the incident light ILL on the photodiodes PD corresponding to the pixels, respectively, and suppress the incident light ILL from erroneously entering photodiodes PD for adjacent pixels.

According to the second embodiment, the silicon dioxide films 17 are provided at a predetermined depth and function as a stopper during formation of the waveguide holes 81. Therefore, variations in the etching amount of the semiconductor substrate 10 are suppressed. Furthermore, the recesses 50 are formed by removing the silicon dioxide films 17 by wet etching in the second embodiment. Meanwhile, there are crystal defects in the front surfaces 40a of the substrate protruding portions 40. Furthermore, according to the second embodiment, the thicknesses TH of the semiconductor substrate 10 between the recesses 50 and the photodiodes PD are determined by the formation positions of the silicon dioxide films 17 (the introduction positions of the oxygen 15), respectively. Accordingly, the second embodiment can also achieve effects identical to those of the first embodiment.

### First Modification

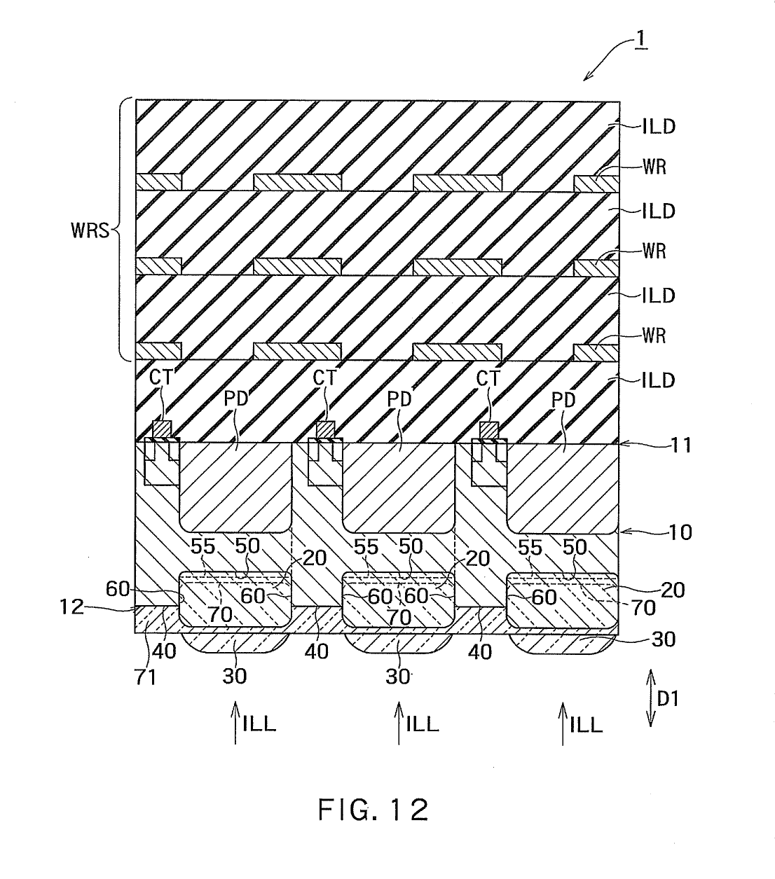

FIG. 12 is a cross-sectional view showing an example of a configuration of the photo sensor 1 according to a first modification of the first embodiment. The photo sensor 1 according to the first modification further includes a transparent body 71 between the color filters 20 and the lenses 30. The transparent body 71 is provided also on the substrate protruding portions 40 to flatten concaves and convexes of the color filters 20 and the substrate protruding portions 40. Other configurations of the first modification can be identical to corresponding ones of the first embodiment.

While the color filters 20 are protruded from the substrate protruding portions 40 in the first modification, the transparent body 71 flattens the concaves and convexes of the color filters 20 and the substrate protruding portions 40. Accordingly, the lenses 30 are formed on a flat surface of the transparent body 71 and the lenses 30 are formed easily. Furthermore, the first modification can achieve effects identical to those of the first embodiment.

### Second Modification

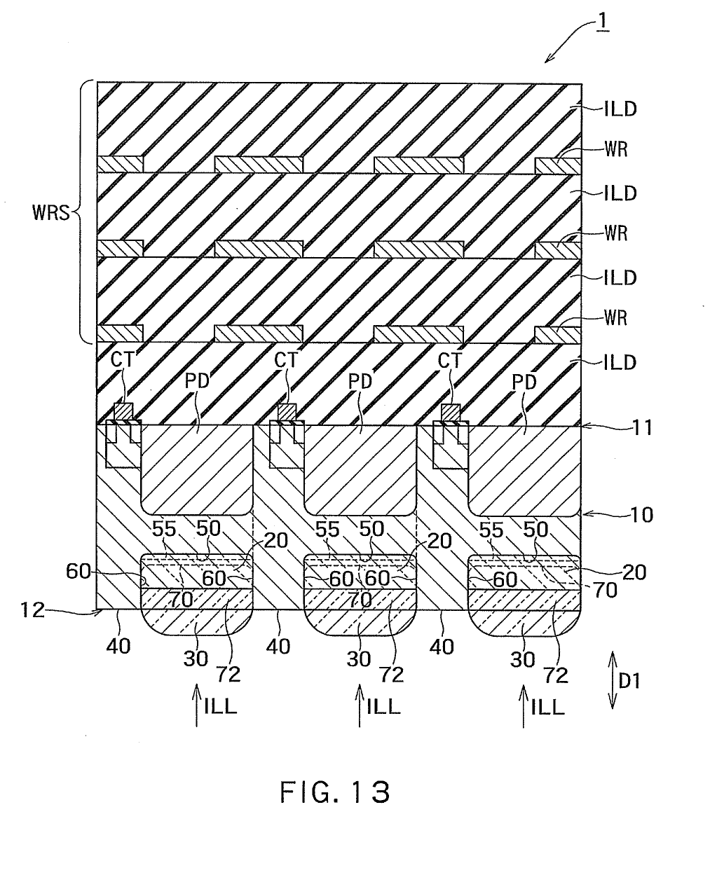

FIG. 13 is a cross-sectional view showing an example of a configuration of the photo sensor 1 according to a second modification of the first embodiment. The photo sensor 1 according to the second modification further includes transparent bodies 72 between the color filters 20 and the lenses 30, respectively. The transparent bodies 72 are not provided on the substrate protruding portions 40 and are embedded in the recesses 50, respectively. Concaves and convexes of the color filters 20 and the substrate protruding portions 40 are flattened. Other configurations of the second modification can be identical to corresponding ones of the first embodiment.

While the color filters 20 are recessed from the substrate protruding portions 40 in the second modification, the transparent bodies 72 are embedded in the recesses 50 to flatten the concaves and convexes of the color filters 20 and the substrate protruding portions 40, respectively. Accordingly, the lenses 30 are formed on flat surfaces of the transparent bodies 72, respectively, and the lenses 30 are formed easily. Furthermore, the second modification can achieve effects identical to those of the first embodiment.

### Third Modification

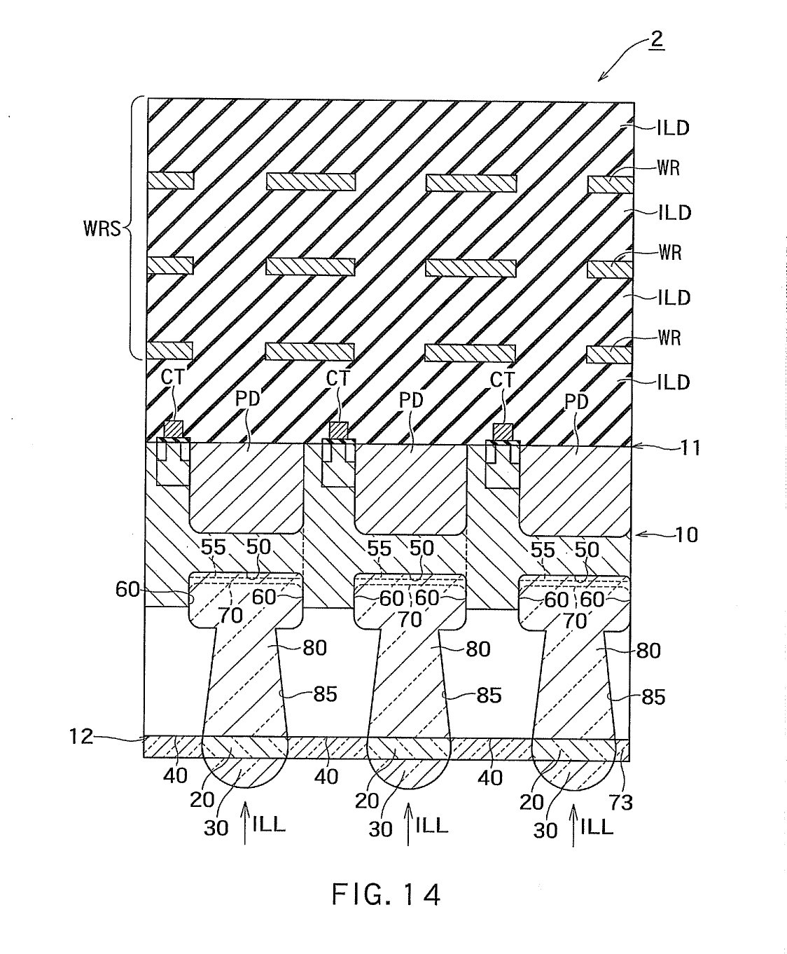

FIG. 14 is a cross-sectional view showing an example of a configuration of the photo sensor 2 according to a third modification of the second embodiment. The photo sensor 2 according to the third modification further includes a transparent body 73 that flattens concaves and convexes of the color filters 20 and the substrate protruding portions 40. Other configurations of the third modification can be identical to corresponding ones of the second embodiment.

While the color filters 20 are protruded from the substrate protruding portions 40 in the third modification, the transparent body 73 flattens the concaves and convexes of the color filters 20 and the substrate protruding portions 40. Accordingly, the lenses 30 are formed on a flat surface of the transparent body 73 and the lenses 30 are formed easily. Furthermore, the third modification can achieve effects identical to those of the second embodiment.

### Fourth Modification

FIG. 15 is a cross-sectional view showing an example of a configuration of the photo sensor 2 according to a fourth modification of the second embodiment. In the fourth modification, the color filters 20 are provided inside of the waveguide holes 81. The lenses 30 are formed on a flat surface including the color filters 20 and the substrate protruding portions 40. Accordingly, the lenses 30 are formed easily. Furthermore, the fourth modification can achieve effects identical to those of the second embodiment.

### Fifth Modification

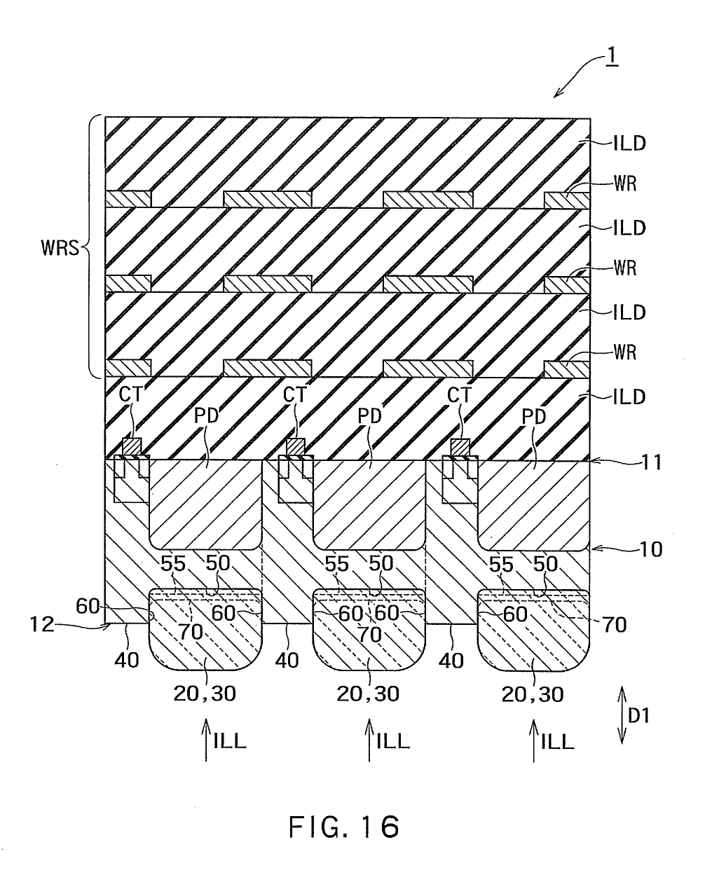

FIG. 16 is a cross-sectional view showing an example of a configuration of the photo sensor 1 according to a fifth modification of the first embodiment. In the photo sensor 1 according to the fifth modification, the color filters 20 and the lenses 30 are integrally formed. It can be said that the color filters 20 also have a function as lenses by forming the color filters 20 in a lens shape. In this case, there is no need to form the color filters 20 and the lenses 30 individually and thus the manufacturing step of the photo sensor 1 can be shortened. Furthermore, the fifth modification can achieve effects identical to those of the second embodiment. The fifth modification can be also applied to the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A photo sensor comprising:
a semiconductor substrate;
a plurality of photodiodes on a first surface of the semiconductor substrate;
a plurality of photodetective filters corresponding to the photodiodes on a second surface of the semiconductor substrate opposite to the first surface;
a plurality of lenses corresponding to the photodetective filters so as to respectively cover the photodetective filters; and
protruding portions protruded on the second surface between adjacent ones of the photodetective filters.

2. The photo sensor of claim 1, wherein the second surface of the semiconductor substrate is recessed at portions where the photodetective filters are located and protruded at portions where the protruding portions are located to be formed in a concave-convex shape.

3. The photo sensor of claim 1, further comprising a plurality of transparent bodies between the semiconductor substrate and the photodetective filters on the second surface of the semiconductor substrate.

4. The photo sensor of claim 1, wherein the photodetective filters are color filters.

5. The photo sensor of claim 1, wherein interfaces between side surfaces of the photodetective filters and side surfaces of the protruding portions reflect light incident on the photodetective filters.

6. The photo sensor of claim 1, wherein the protruding portions separate respective optical paths of the photodiodes.

7. The photo sensor of claim 5, wherein the protruding portions separate respective optical paths of the photodiodes.

8. The photo sensor of claim 1, further comprising waveguides between adjacent ones of the protruding portions.

9. A photo sensor comprising:
a semiconductor substrate;
a plurality of photodiodes on a first surface of the semiconductor substrate;
a plurality of photodetective filters corresponding to the photodiodes on a second surface of the semiconductor substrate opposite to the first surface;
a plurality of lenses corresponding to the photodetective filters so as to respectively cover the photodetective filters; and
recesses corresponding to the photodiodes and provided on the second surface of the semiconductor substrate.

10. A manufacturing method of a photo sensor, the method comprising:
introducing oxygen below a plurality of photodiode formation regions on a first surface of a semiconductor substrate;
thermally treating the semiconductor substrate to form oxide films of the semiconductor substrate below the photodiode formation regions;
forming a plurality of photodiodes on the first surface of the semiconductor substrate;
polishing or etching a second surface of the semiconductor substrate opposite to the first surface to expose the oxide films;
removing the oxide films to form a plurality of recesses corresponding to the photodiodes;
forming a plurality of photodetective filters in the recesses; and
forming a plurality of lenses on the photodetective filters.

11. The method of claim 10, wherein the oxide films are exposed by entirely polishing the second surface of the semiconductor substrate when the oxide films are to be exposed.

12. The method of claim 10, wherein the semiconductor substrate is selectively etched from the second surface of the semiconductor substrate to the oxide films using a lithography technique and an etching technique when the oxide films are to be exposed.

13. The method of claim 10, further comprising forming a plurality of transparent bodies in the recesses before forming the photodetective filters.

14. The method of claim 10, wherein the photodetective filters are color filters.
